(19) United States
(12) Patent Application Publication
(10) Pub. No.: US 2014/0264784 A1
(43) Pub. Date: Sep. 18, 2014

(54) Metal Shielding on Die Level

(71) Applicant: NXP B. V., Eindhoven (NL)

(72) Inventors: Chung Hsiung Ho, Kaohsiung City (TW); Wen Hung Huang, Kaohsiung City (TW); Wen-Jen Kuo, Kaohsiung City (TW); W.H. Lin, Kaohsiung City (TW); ChihLi Huang, Kaohsiung City (TW); Pao Tung Pan, Kaohsiung City (TW); I. Pin Chen, Kaohsiung City (TW); Li Ching Wang, Kaohsiung City (TW)

(21) Appl. No.: 13/804,088

(22) Filed: Mar. 14, 2013

(51) Int. Cl. H01L 23/552; H01L 21/78

(52) U.S. Cl. CPC H01L 23/552; H01L 21/78
USPC 257/659; 438/114

(57) ABSTRACT

Consistent with an example embodiment, there is a semiconductor device having a front-side surface, back-side surface, and vertical surfaces. The semiconductor device comprises an active device die having electrical contacts on the front-side surface. A metal shield is plated on the back-side surface and the vertical surfaces of the active device die. Conductive links connect the plated metal shield to selected electrical contacts on the front-side surface.

### FIELD

The embodiments of the present invention relate to semiconductor device packaging and, more particularly, to bare die/WLCSP packaging having modifications that enhance radio frequency (RF) shielding of the active device die as it is mounted into a system.

### BACKGROUND

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

The packaging of an IC device is increasingly playing a role in its ultimate performance. In portable electronic devices such as PDAs, smart phones, tablet computers, etc., the processing requirements are scaling upward into the giga-hertz realm, as micro-processor circuits, radio transmitter/receiver circuits are running faster. Consequently, the associated electronics are subjected to more electromagnetic interference (EMI) radiation or radio frequency interference (RFI) and the attendant effects; it is disturbance that affects an electrical circuit due to either electromagnetic induction or electromagnetic radiation emitted from an external source. The disturbance may interrupt, obstruct, or otherwise degrade or limit the effective performance of the circuit. For example, these effects can range from a simple degradation of data to a total loss of data.

RF shielding may be adapted for the high-performance device die. However, this shielding cannot use up precious space within the portable device system assembly.

There exists a need for RF shielding that may provide protection to an active device die, yet not substantially add to the form factor of the active device die.

### SUMMARY

The present disclosure has been found useful in the packaging of semiconductor devices which find their way into portable electronic devices. An RF shield is plated onto the bare die; the plated RF shield does not appreciably add to the device die's overall dimensions. After the device die is soldered onto the system printed circuit board, the plated RF shield forms a continuous RF shield surrounding all six sides.

In an example embodiment, there is a method for manufacturing a silicon device having RF shielding from a wafer substrate having a front-side surface and a back-side surface. The method comprises, attaching the back-side surface of the wafer substrate, having a plurality of active devices on the front-side surface, onto a sawing film. The wafer substrate is sawed and the sawing film is stretched to separate the plurality of active devices into separate devices, each separate device having a front-side surface. An adhesive film is applied onto the separate devices, the adhesive film protecting the front-side surface of each separate device and leaving other surfaces exposed. The sawing film is removed exposing the back-side surface of each separate device. The separate devices are dipped into a plating solution; the separate devices are left in the plating solution until the plating solution deposits metal of a thickness onto expose surfaces of each of the separate devices.

In another example embodiment, a semiconductor device has a front-side surface, back-side surface, and vertical surfaces, the semiconductor device comprises, an active device die having electrical contacts on the front-side surface. A plated metal shield is on the back-side surface and the vertical surfaces of the active device die; conductive links connect the plated metal shield to selected electrical contacts on the front-side surface.

In yet another example embodiment, a system having RF shielding, comprises an RF shielded semiconductor device; the RF shielded semiconductor device includes an active device die having bump contacts on the front-side surface, a plated metal shield on the back-side surface and vertical surfaces of the active device die, and conductive links connecting the plated metal shield to selected bump contacts on the front-side surface, wherein the selected bump contacts are ground connections. The system further includes a printed circuit board (PCB) substrate, including grounding connections on an insulated substrate. The RF shielded semiconductor device ground connections are coupled to PCB grounding connections; said connections form an RF shield surrounding the entire RF shielded semiconductor device.

In another example embodiment, there is a method for manufacturing a silicon device having RF shielding from a wafer substrate having a front-side surface and a back-side surface. The method comprises attaching the back-side surface of the wafer substrate, having a plurality of active devices on the front-side surface, onto a sawing film. The wafer substrate is sawed and the sawing film is stretched to separate the plurality of active devices into separate devices, each separate device having a front-side surface. An adhesive film is applied onto the separate devices, the adhesive film protecting the front-side surface of each separate device and leaving other surfaces exposed. Removing the sawing film exposes the back-side surface of each separate device. Metal is sputtered onto the exposed surfaces of the separate devices until the metal attains a prescribed thickness.

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIG. 1A-1C (Prior Art) is an example of a metal shielding system;

FIG. 2 (Prior Art) is another example of a metal shielding system for a WLCSP device;

FIGS. 3A-3I an example embodiment, according to the present disclosure, of a process for RF shielding active device die;

FIGS. 4A-4D is another example embodiment illustrating and extension of V_{SS} (Ground) connections on the active device die to saw lanes such that on finished active device die, side contact to VSS is possible with the RF shield;

FIGS. 5A-5B illustrates the example active device with the extended V_{SS} connections connecting to the ground plane of the printed circuit board; and

FIG. 6 is a flow diagram, of an example metal shielding process according to the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful in enhancing RF protection for bare die/WLCSP devices as they are assembled onto printed circuit boards. An RF shield is plated onto the bare die. The plated RF shield does not appreciably add to the device die's overall dimensions. After the device die is soldered onto the system printed circuit board, the plated RF shield forms a continuous RF shield surrounding all six sides. Such a process may be integrated into the customary back-end assembly.

Providing a sufficient RF shield is an on-going challenge in the building of portable electronic systems; the RF shield cannot take up too much space. FIGS. 1A-1C illustrate the encapsulation of an example device die 120 in an RF shield package 110. Through connections 125 at the corners and selected ball bonds 130 the power and ground connections within the device die 130 may be connected to corresponding power and ground on a system board. In another example, FIG. 2 illustrates a device die 230 with its ball bonds 220. Such a device may be mounted onto a system board. An RF shield 205 with ball bonds 210 may be enclosed the device die 220. The RF shield 205 is mounted onto grounding connections on the system board. In both examples, however, the RF shield increases the amount of space required on the system boards for the respective device die 130 and 230.

In an example embodiment, a semiconductor wafer is attached to a flexible film held in manufacturing tooling. The wafer is sawn to separate device die; the flexible film may be stretched by the manufacturing tool so as to make more discrete spacing between device die. A thermo tape laminate is applied to the active side (front-side surface) of the device die; a UV exposure cures the laminate to assure adhesion of the device die. The device die are attached to the thermo tape and demounted from the flexible film. The device die are dipped into an aqueous electro-less plating solution; the exposed sides of the device die are plated with a metal. In an example process, prior to electro-less plating, the device die are pre-cleaned in a suitable etch solution and rinsed with de-ionized water so as to remove any contaminants which may adversely affect the adhesion of the plating. An RF shield not adding appreciable dimensions to the device die is attained. Subsequent processing of these RF shielded die prepares them for loading them onto tape and reel for the end user.

Background on electro-less plating may be found in the article titled, “Electroless Deposition by Eugene J. O'Sullivan, IBM Research Division. IBM T.J. Watson Research Center, Yorktown Heights, N.Y., February 2011.

In another example process, the exposed sides of the device die may be dipped into a gel or glue. Upon this gel or glue, the appropriate metal is plated thereon with an electro-less plating process. An example process gel process for gold is presented in granted U.S. Pat. No. 6,194,032 B2 (issued on Feb. 27, 2001) of Lynne M. Svedberg et al. titled, “Selective Substrate Metallization,” and is incorporated by reference in its entirety.

Refer to FIGS. 3A-3D. In an example embodiment, a tooling apparatus 310 to which a flexible UV tape 330 is attached. On the flexible UV tape is a semiconductor wafer 320 having contact regions 360. These contact regions 360 may copper landings, solder bumps or ball bonds, etc. The wafer 320 is sawn apart into device die; to make more discrete separation between the device die 325, the UV tape 330 the tooling apparatus 310 may stretch the flexible UV tape 330. On the topside surfaces (i.e., areas with electrical contacts to the active device region) of the device die 325, a flexible thermo tape is laminated thereon. The device die 325 on the thermo tape 335 are demounted from the UV tape 330. Refer to FIGS. 3E-3G. The device die 325 attached to the thermo tape 335 are dipped into an aqueous solution of silver 340. Other aqueous metal solutions may be used, as appropriate. For example, other metals such as gold, copper, aluminum, zinc, tin, and nickel, etc. may be used, but the concept in not so limited.

In an example process using electro-less nickel plating, the layer thickness also affects the coating's resistance: layers with a thickness in the 2 μm to 10 μm range may be useful as a passivation to resist corrosion; those in the 5 μm to 10 μm range may provide resistance to mild mechanical wear. A higher level of protection may be attainable with a coating having a thickness in the 10 μm to 25 μm range, while the highest degree of protection would trend toward thickness values ranging from 25 μm to 50 μm and over 50 μm, respectively. Table 1 outlines some example elements plated onto device die so that the device die have shielding. For the thicker plating (i.e., nickel), the device die has the additional feature of scratch protection from assembly handling.

In an example embodiment, if a gel/glue process is used, the lower range of thickness is determined by the amount of filler material blended with the particular metal shielding. Of course, a thicker gel/glue would enhance the mechanical protection of the device die.

TABLE 1
Example Metals for Shielding Device Die

| Element | Lower Range (μm) | Upper Range (μm) |
|---|---|---|
| Cu | 0.05 | 1 |
| Ni | 2 | 125 |
| Au | 0.05 | 0.5 |
| Ag | 0.05 | 0.5 |
| Sn | 0.15 | 0.5 |

The device die 325 having a plating layer 345 are removed and the thermo tape 335 they are mounted on is cured and undergoes a thermal release. The plated device die 325 are mounted on blue tape 355 loaded into another tooling apparatus 350. With a vacuum tool 20, the device die 325 having the plated RF shielding 345 are spooled up into a tape and reel for the end user. Refer to FIG. 31. The finished die 325 is surrounded by the plated RF shield 345 on its underside and vertical faces. When attached at the ball bonds 360, the shielding is coupled to the power or ground plane of the system board.

Refer to FIGS. 4A-4D. In an example embodiment according to the disclosure, an array 400 of device die on their undersides has connection points 420 and 425 which extend to the saw lanes. An enlarged view of a single device 410 (with the device boundary in dashed lines) shows a closer view of connection areas 420 and 425. Refer to FIG. 4C. The connection areas 420 and 425 are designed in the sawing lane area. These saw-lane connection areas 420 are shown in the RF shielded 440 device die 430. Selected ball bonds 435 are coupled to the saw-lane connection areas 420 and 425 which in turn are coupled to the RF shield 440. After wafer sawing, saw-lane connection areas 420 and 425 are exposed at the side wall as shown in FIG. 4C. The metal shielding 440 is connected to these areas 420 and 425. Through a redistribution layer (RDL) 422, these areas 420 and 425 are connected to pins (or solder balls, ball bonds, pad landings, etc.) defined as ground. An RDL is an extra metal layer on a chip or substrate that makes the I/O, power and ground pads of an integrated circuit available in other locations 423; in the instant example, as with connection areas 420 and 423, these other locations 423 are at the active device boundary edges (see dashed lines). For example, four areas of the RDL 422 are denoted by the arrows in FIG. 4B. Connection areas 420 and 425 have electrical connection to RDL 422 at pre-determined locations.

Refer to FIG. 5A. In an example embodiment, a device 500 is mounted onto a system board 510. Device die 530 is surrounded by the plated RF shield 540. Selected ball bonds 550 and 550′ are coupled to shield connections 545 and 545′. The device 500 is soldered to PCB landings 555 and 555′ at ball bonds 550 and 550′. FIG. 5B shows a graphical representation of the device die 530 now surrounded by a grounding shield 560.

Refer to FIG. 6. In an example process according to the disclosure, a wafer of active devices is mounted on a UV tape 100. The mounted wafer is sawed and to space apart die, the UV tape is stretched 110. A thermo tape is laminated to the active device side 120. This serves to protect the devices from subsequent handling. The separated device die are demounted from the UV tape as they are transferred to the thermo tape 130. Exposed surfaces of the device are plated in a room-temperature plating 140. Silver may be used, but other metals may be used, as well. The thermo tap upon which the device die are mounted is cured 150; an adhesion release is performed 160. The now-plated device die on the thermo tape are placed on an additional blue tape 170. The plated device die are transferred die-by-die with a vacuum apparatus and spooled up on tape and reel 180. The tape and reel of plated device die is shipped to the end user 190.

Rather than dipping the exposed sides of the device die into an aqueous plating solution, the metal may be applied to the exposed sides of the device die through a sputter deposition process. Sputter deposition is a way of depositing thin films by sputtering which involves eroding material from a target source onto the device die. In some applications, sputtering may involve the deposition of an appropriate metal for RF and EMI shielding followed by a deposition of a protective plastic film. For bare die/WLCSP, the protection, if of sufficient thickness, the plastic film may reduce the likelihood of chipping during handling and assembly into PCB subsystems electronic products. In an example process, for RF shielding a range of about 0.1 μm to about 1 μm is sufficient. For mechanical protection a thickness greater than about 3 μm may be appropriate.

Numerous other embodiments of the invention will be apparent to persons skilled in the art without departing from the spirit and scope of the invention as defined in the appended claims.

1. A method for manufacturing a silicon device having RF shielding from a wafer substrate having a front-side surface and a back-side surface, the method comprising:
attaching the back-side surface of the wafer substrate, having a plurality of active devices on the front-side surface, onto a sawing film;
sawing the wafer substrate, and stretching the sawing film to separate the plurality of active devices into separate devices, each separate device having a front-side surface;
applying an adhesive film onto the separate devices, the adhesive film protecting the front-side surface of each separate device and leaving other surfaces exposed;
removing the sawing film exposing the back-side surface of each separate device;
dipping the separate devices into a plating solution, and
leaving the separate devices in the plating solution until the plating solution deposits metal of a thickness onto exposed surfaces of each of the separate devices.

2. The method as recited in claim 1, wherein the dipping the separate devices, further includes,
pre-cleaning the exposed surfaces of each of the separate devices.

3. The method of claim 1, wherein prior to dipping, the exposed surfaces of the separate devices are coated with a gel/glue material of a thickness, the gel/glue material being receptive to the plating solution, whereupon metal deposits onto the gel/glue material.

4. The method as recited in claim 1, wherein in the deposited metal is one from the group including: silver (Ag), gold (Au), copper (Cu), aluminum (Al), zinc (Zn), tin (Sn), and nickel (Ni).

5. The method as recited in claim 4, wherein the thickness of the deposited metal is as least 0.05 μm.

6. The method as recited in claim 5, wherein the thickness of the deposited metal is in the range of about 0.05 μm to about 125 μm.

7. The method as recited in claim 5, wherein the thickness of the deposited metal is in the range of about 0.05 μm to about 10 μm.

8. The method as recited in claim 2, further comprising,
attaching an additional tape on the adhesive film; and
transferring the separate devices onto tape and reel.

9. A semiconductor device having a front-side surface, back-side surface, and vertical surfaces, the semiconductor device comprising:
an active device die having electrical contacts on the front-side surface;
a plated metal shield on the back-side surface and the vertical surfaces of the active device die; and
conductive links connecting the plated metal shield to selected electrical contacts on the front-side surface.

10. The semiconductor device as recited in claim 9, wherein the conductive links include,
a redistribution layer (RDL) connecting electrical contacts on the front-side surface to defined boundary edge contacts of the active device; and
selected boundary edge contacts coupled to saw-lane connection areas.

11. The semiconductor device as recited in claim 9, wherein the selected electrical contacts are ground connections.

12. The semiconductor device as recited in claim 10, wherein the saw-lane connection areas are coupled to ground.

13. System having RF shielding, the system comprising:
an RF shielded semiconductor device, including,
an active device die having bump contacts on the front-side surface;
a plated metal shield on the back-side surface and vertical surfaces of the active device die; and
conductive links connecting the plated metal shield to selected bump contacts on the front-side surface, wherein the selected bump contacts are ground connections;
a printed circuit board (PCB) substrate, including grounding connections on an insulated substrate;
wherein the RF shielded semiconductor device ground connections are coupled to PCB grounding connections, said connections forming an RF shield surrounding the entire RF shielded semiconductor device.

14. The system as recited in claim 13, wherein the conductive links are provided by a redistribution layer applied to the front-side surface of the active device die.

15. A method for manufacturing a silicon device having RF shielding from a wafer substrate having a front-side surface and a back-side surface, the method comprising:
attaching the back-side surface of the wafer substrate, having a plurality of active devices on the front-side surface, onto a sawing film;
sawing the wafer substrate, and stretching the sawing film to separate the plurality of active devices into separate devices, each separate device having a front-side surface;
applying an adhesive film onto the separate devices, the adhesive film protecting the front-side surface of each separate device and leaving other surfaces exposed;
removing the sawing film exposing the back-side surface of each separate device; and
sputtering metal onto the exposed surfaces of the separate devices until the metal attains a prescribed thickness.

16. The method as recited in claim 15, further comprising sputtering plastic onto the sputtered metal.

17. The method as recited in claim 15, wherein in the sputtered metal is one from the group including: silver (Ag), gold (Au), copper (Cu), aluminum (Al), zinc (Zn), tin (Sn), and nickel (Ni).

18. The method as recited in claim 17, wherein the thickness of the sputtered metal is as least 0.05 μm.

19. The method as recited in claim 18, wherein the thickness of the sputtered metal is in the range of about 0.05 μm to about 50 μm.

20. The method as recited in claim 16, wherein the thickness of the sputtered plastic is at least 3 μm.
